(19) United States
(12) Patent Application Publication
(10) Pub. No.: US 2026/0301461 A1
(43) Pub. Date: Oct. 1, 2026

(54) DISPLAY DEVICE AND ELECTRONIC DEVICE

(71) Applicant: SAMSUNG DISPLAY CO., LTD., YONGIN-SI (KR)

(72) Inventors: Seoyoung LIM, Yongin-si (KR); KWANG SOO BAE, Yongin-si (KR); HYANG-A PARK, Yongin-si (KR); Goeen JEONG, Yongin-si (KR); Soo Yeong HONG, Yongin-si (KR)

(21) Appl. No.: 19/454,948

(22) Filed: Jan. 21, 2026

(30) Foreign Application Priority Data
Mar. 28, 2025 (KR) 10-2025-0040303

(51) Int. Cl. G06V 40/13; G01L 1/24; H04N 23/63; H05K 5/03; H10K 59/80

(52) U.S. Cl. CPC G06V 40/1318; G01L 1/24; H05K 5/03; H10K 59/873; H04N 23/63

(57) ABSTRACT

A display device including a display panel including a substrate, a plurality of sensors disposed on the substrate, the plurality of sensors each including a light-receiving element, and a plurality of pixels, each of the plurality of pixels including a light-emitting element adjacent to the light-receiving element, a window disposed on the display panel, and a cushion layer disposed on the window, wherein an upper surface of the cushion layer is deformable according to an external pressure.

### CROSS-REFERENCE TO RELATED APPLICATION(S)

This application claims priority under 35 U.S.C. § 119 to and benefits from Korean Patent Application No. 10-2025-0040303 filed on Mar. 28, 2025 in the Korean Intellectual Property Office, the entire contents of which is incorporated by reference herein.

### TECHNICAL FIELD

The disclosure herein relates to a display device and an electronic device.

### DISCUSSION OF THE RELATED ART

An electronic device, which provides an image to a user such as a smartphone, a digital camera, a laptop computer, a navigation unit, or a smart television includes a display device for displaying an image. The display device includes a display panel for generating an image, an input device such as an input sensing part, a camera for capturing an external image, and various sensors.

The input sensing part may be disposed on the display panel and to sense a user's touch. The input sensing part may be manufactured as a separate panel and then attached to the display panel. The sensors may include a fingerprint sensor, a proximity sensor, an illuminance sensor, a pressure sensor, and the like. The fingerprint sensor senses a fingerprint provided onto the display panel, while the pressure sensor senses pressure exerted onto the display panel. What is needed is an improved design for a display device and an electronic device that can more accurately determine a pressure of an external object such as a user's finger that contacts and exerts pressure on a front surface of the display device.

### SUMMARY

Embodiments of the disclosure provides a display device which may improve accuracy of fingerprint sensing and pressure sensing.

Embodiments of disclosure also provides an electronic device which may improve accuracy of fingerprint sensing and pressure sensing.

An embodiment of the disclosure provides a display device including a display panel including a substrate, a plurality of sensors disposed on the substrate, each of the plurality of sensors including a light-receiving element, and a plurality of pixels, each of the plurality of pixels including a light-emitting element adjacent to the light-receiving element, a window disposed on the display panel, and a cushion layer disposed on the window, wherein an upper surface of the cushion layer is deformable upon application of an external pressure.

In an embodiment, light generated by the pixels may be incident onto an external object. The external object may be configured to exert the external pressure to the cushion layer, and the plurality of sensors may be configured to receive and sense light reflected off of the external object.

In an embodiment, an amount of deformation of the cushion layer may increase and an amount of light received by the plurality of sensors may increase as the external pressure increases.

In an embodiment, an amount of deformation of the cushion layer may increase and a number of the plurality of sensors which receive light reflected off of the external object may increase as the external pressure increases.

In an embodiment, an amount of deformation of the cushion layer may increase and a size of a sensing area of the display panel, which receives light reflected off of the external object may increase as the external pressure increases.

In an embodiment, an amount of deformation of the cushion layer may decrease and an amount of light received by the sensors may decrease as the external pressure decreases.

In an embodiment, an amount of deformation of the cushion layer may decrease and number of the sensors which receive light reflected off of the external object may decrease as the external pressure decreases.

In an embodiment, an amount of deformation of the cushion layer may decrease and a size of a sensing area of the display panel which receives light reflected off of the external object may decrease as the external pressure decreases.

In an embodiment, the display device may further include a timing controller configured to receive sensing signals from the plurality of sensors, and light generated by the plurality of pixels may be incident onto an external object that applies the external pressure to the cushion layer.

In an embodiment, the timing controller may be configured to determine the external pressure exerted by the external object according to sensing signals received from the plurality of sensors, and the sensing signals pertain to a size of a sensing area and an amount of light received by the plurality of sensors.

In an embodiment, the timing controller may be configured to determine an increase in the external pressure upon an increase in a size of a sensing area.

In an embodiment, the timing controller may be configured to determine a decrease in the external pressure upon a decrease in a size of the sensing area.

In an embodiment, the timing controller may be configured to output fingerprint information corresponding to the sensing signals.

In an embodiment, the cushion layer may include a transparent polymer and a transparent urethane material.

In an embodiment, light generated by the pixels may be incident onto an external object which applies the external pressure to the cushion layer, and an angle between the light incident onto the external object and light reflected off of the external object and incident onto each of the plurality of sensors may be about 71 degrees or less.

In an embodiment of the disclosure, a display device includes a display panel which includes a substrate, a plurality of sensors disposed on the substrate, each of the plurality of sensors including a light-receiving element, and a plurality of pixels, each of the plurality of pixels including a light-emitting element adjacent to the light-receiving element, a window disposed on the display panel, and a timing controller configured to receive sensing signals from the plurality of sensors, wherein light generated by the plurality of pixels is incident onto an external object that is in contact with the window, and the plurality of sensors are configured to receive and sense light reflected off of the external object, and the timing controller is configured to determine an amount of external pressure exerted by the external object according to sensing signals pertaining to a size of a sensing area and an amount of light received by the plurality of sensors.

In an embodiment, an amount of light received by the plurality of sensors may increase and a size of a sensing area of the display panel may increase as a contact area between the external object and the window increases, and an amount of light received by the plurality of sensors may decrease and a size of a sensing area of the display panel may decrease as the contact area between the external object and the window decreases.

In an embodiment, the external object may be in direct contact with the window, and the window may not be deformable according to pressure exerted by the external object.

In an embodiment of the disclosure, an electronic device includes a camera module and a display device configured to display an image corresponding to an image captured by the camera module, wherein the display device includes a display panel including a substrate, a plurality of sensors disposed on the substrate, each of the plurality of sensors including a light-receiving element, and a plurality of pixels, each of the plurality of pixels including a light-emitting element adjacent to the light-receiving element, a window disposed on the display panel, and a cushion layer disposed on the window, and an upper surface of the cushion layer is deformable according to an external pressure.

In an embodiment, the cushion layer may be configured to be optically transparent to light produced by the plurality of pixels, and the plurality of sensors may sense both an amount of light reflected off of an external object exerting the external pressure and a size of a sensing area corresponding to an area of ones of the plurality of sensors that receive the light reflected off of the external object.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view of a display device according to an embodiment of the disclosure;

FIG. 2 is an example diagram illustrating a cross section of the display device illustrated in FIG. 1;

FIG. 3 is an example diagram illustrating a cross section of a display panel illustrated in FIG. 2;

FIG. 4 is a block diagram of the display device illustrated in FIG. 1;

FIG. 5 is a diagram illustrating an equivalent circuit of a pixel among pixels illustrated in FIG. 4 and a sensor adjacent to the pixel;

FIG. 6 is an example diagram illustrating a cross section of a light-emitting element, a first transistor, a fourth transistor and a sixth transistor of the pixel illustrated in FIG. 5;

FIG. 7 is an example diagram illustrating a cross section of a light-receiving element, a first transistor and a second transistor of the sensor illustrated in FIG. 5;

FIG. 8A is an example diagram illustrating a state in which a fingerprint is sensed by the sensors illustrated in FIGS. 5 and 7;

FIG. 8B is an example diagram illustrating a state in which pressure is sensed by the sensors illustrated in FIGS. 5 and 7;

FIGS. 9A and 9B are cross-sectional views in more detail illustrating a state in which pressure is sensed by the sensors illustrated in FIG. 7;

FIGS. 10A and 10B are cross-sectional views in more detail illustrating a state in which pressure is sensed by the sensors illustrated in FIG. 7; and

FIG. 11 is a block diagram of an electronic device according to embodiments of the disclosure.

### DETAILED DESCRIPTION OF THE EMBODIMENTS

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. While each drawing may represent one or more particular embodiments of the present disclosure, drawn to scale, such that the relative lengths, thicknesses, and angles can be inferred therefrom, it is to be understood that the disclosure is not necessarily limited to the relative lengths, thicknesses, and angles shown. Changes to these values may be made within the spirit and scope of the present disclosure, for example, to allow for manufacturing limitations and the like.

It will be understood that, although the terms “first”, “second”, etc. may be used herein to describe various elements, the elements are not to be limited by these terms. These terms are used to distinguish one element from another element. For instance, a first element discussed below could be termed a second element without departing from the scope of the disclosure. Similarly, a second element could be termed a first element. In this specification, the singular expressions “a”, “an” and “the” are intended to include the plural forms as well, unless the context clearly indicates otherwise.

The terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

According to embodiments of the disclosure, there is provided a design for a display device and an electronic device that includes the same that indirectly senses external pressure of a user's finger on a display surface of the device. Sensors are embedded in the display panel that directly sense an amount of light originating from the pixels that reflects off of the finger, and also senses a size of a sensing area corresponding to sensors that receive light reflected off of the finger. The sensors produce sensing signals pertain to the amount of light reflected and a size of the sensing area to a timing controller to determine the pressure of the finger on the front of the display panel.

Another aspect of the embodiments of the disclosure is to include a cushion layer on a front side of the window, the cushion layer is both transparent to light produced by the pixels and is deformable according to exerted pressure of a user's finger. Thus if more pressure is exerted, more deformation of the cushion layer occurs, resulting in more reflected light reaching the sensors and a greater sensing area to facilitate determination of a pressure exerted by a user's finger.

Hereinafter, embodiments of the disclosure are described with reference to the drawings.

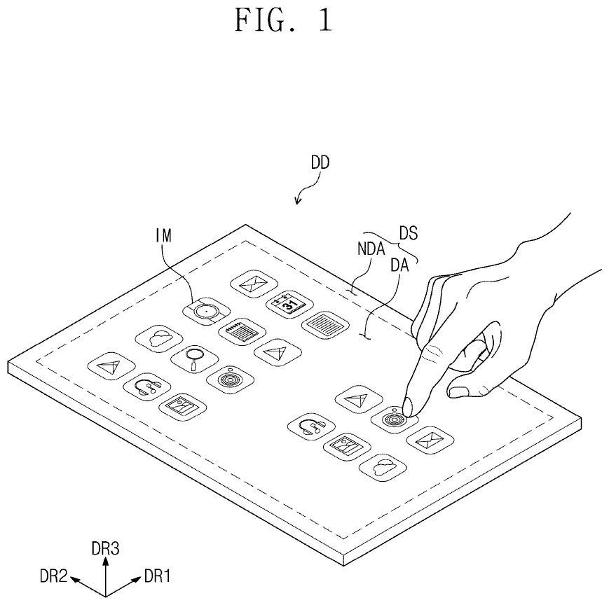

FIG. 1 is a perspective view of a display device according to an embodiment of the disclosure.

Referring to FIG. 1, a display device DD according to an embodiment of the disclosure may have a rectangular shape having short sides extending in a first direction DR1 and long sides extending in a second direction DR2 intersecting the first direction DR1. However, an embodiment of the disclosure is not necessarily limited thereto, and the display device DD may have various shapes such as a circular shape or a polygonal shape.

Hereinafter, a direction substantially perpendicular to a plane defined by the first direction DR1 and the second direction DR2 may be defined as a third direction DR3. In this specification, the wording “in a plan view” may be defined as a state of being viewed in a direction opposite to the third direction DR3 (i.e., from above).

An upper surface of the display device DD may be defined as a display surface DS and have a plane defined by the first direction DR1 and the second direction DR2. Images IM generated by the display device DD may be provided to a user through the display surface DS.

The display surface DS may include a display region DA and a non-display region NDA around the display region DA. The display region DA may display an image, and the non-display region NDA might not display an image. The non-display region NDA may be printed in color and may surround the display region DA and define an edge of the display device DD.

The display device DD may be used in large-sized electronic devices such as a television, a monitor, or an outdoor billboard. The display device DD may be used in medium and small-sized electronic devices such as a personal computer, a laptop computer, a personal digital terminal, a car navigation unit, a game console, a smartphone, a tablet, or a camera. However, these are presented simply examples, and the display device DD may be used in other electronic devices as long as the display device DD does not depart from the disclosure.

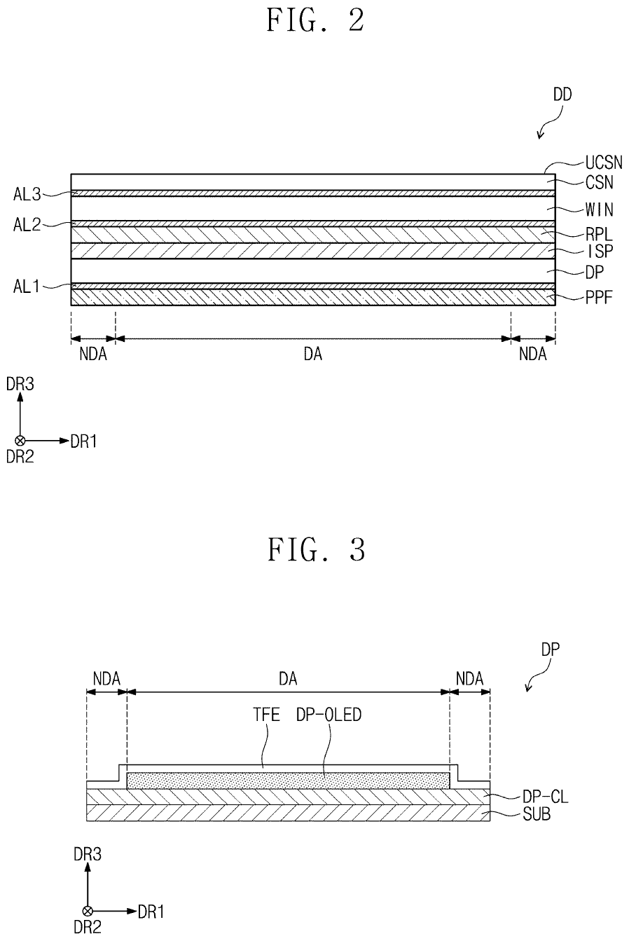

FIG. 2 is an example diagram illustrating a cross section of the display device illustrated in FIG. 1.

By way of example, FIG. 2 illustrates a cross section of the display device DD viewed in the second direction DR2.

Referring to FIG. 2, the display device DD may include a display panel DP, an input sensing part ISP, an anti-reflective layer RPL, a window WIN, a panel protective film PPF, a cushion layer CSN and first to third adhesive layers AL1, AL2 and AL3.

The display panel DP may be a flexible display panel. The display panel DP according to an embodiment of the disclosure may be an emissive display panel and is not necessarily limited. For example, the display panel DP may be an organic light-emitting display panel or an inorganic light-emitting display panel. An emission layer of the organic light-emitting display panel may include an organic light-emitting material. An emission layer of the inorganic light-emitting display panel may include quantum dots, quantum rods, and the like. Hereinafter, the display panel DP is described as an organic light-emitting display panel.

The input sensing part ISP may be disposed on the display panel DP. The input sensing part ISP may include multiple sensing parts for sensing an external input in a capacitive manner. The input sensing part ISP may be manufactured directly on the display panel DP when the display device DD is manufactured. However, an embodiment of the disclosure is not necessarily limited thereto, and the input sensing part ISP may be manufactured as a panel separate from the display panel DP and subsequently attached to the display panel DP via an adhesive layer.

The anti-reflective layer RPL may be disposed on the input sensing part ISP. The anti-reflective layer RPL may be manufactured directly on the input sensing part ISP when the display device DD is manufactured. However, an embodiment of the disclosure is not necessarily limited thereto, and the anti-reflective layer RPL may be manufactured as a separate panel and subsequently attached to the input sensing part ISP via an adhesive layer.

The anti-reflective layer RPL may be defined as an external light anti-reflective film. The anti-reflective layer RPL may reduce reflectance of external light incident from above the display device DD. The external light might not be viewed by a user due to the anti-reflective layer RPL.

When external light propagating toward the display panel DP is reflected off the display panel DP back to an external user, the user may view the external light as in the case of viewing light reflected off a mirror. By way of example, the anti-reflective layer RPL may include multiple color filters to prevent such phenomenon which display the same color as pixels of the display panel DP.

The color filters may filter external light with the same color as the pixels. In this case, the external light might not be viewed by a user. However, an embodiment of the disclosure is not necessarily limited thereto, and the anti-reflective layer RPL may include a retarder and/or a polarizer to reduce reflectance of external light.

The window WIN may be disposed on the display panel DP and on the anti-reflective layer RPL. The window WIN may protect the display panel DP, the input sensing part ISP and the anti-reflective layer RPL from external scratches and impacts.

The cushion layer CSN may be disposed on the window WIN. An upper surface UCSN of the cushion layer CSN may deform according to external pressure. When an external object touches the cushion layer CSN, the upper surface UCSN of the cushion layer CSN may deform according to external pressure exerted by the external object. Light generated by the display panel DP may reflect off the external object. A path of light reflected off the external object may vary according to the external pressure. A detailed descriptions thereof will be made later.

The panel protective film PPF may be disposed below the display panel DP. The panel protective film PPF may protect a lower portion of the display panel DP. The panel protective film PPF may include a flexible plastic material such as polyethyleneterephthalate (PET).

The first adhesive layer AL1 may be disposed between the display panel DP and the panel protective film PPF, and the display panel DP and the panel protective film PPF may be bonded to each other by the first adhesive layer AL1. The second adhesive layer AL2 may be disposed between the window WIN and the anti-reflective layer RPL, and the window WIN and the anti-reflective layer RPL may be bonded to each other by the second adhesive layer AL2. The third adhesive layer AL3 may be disposed between the window WIN and the cushion layer CSN, and the window WIN and the cushion layer CSN may be bonded to each other by the third adhesive layer AL3.

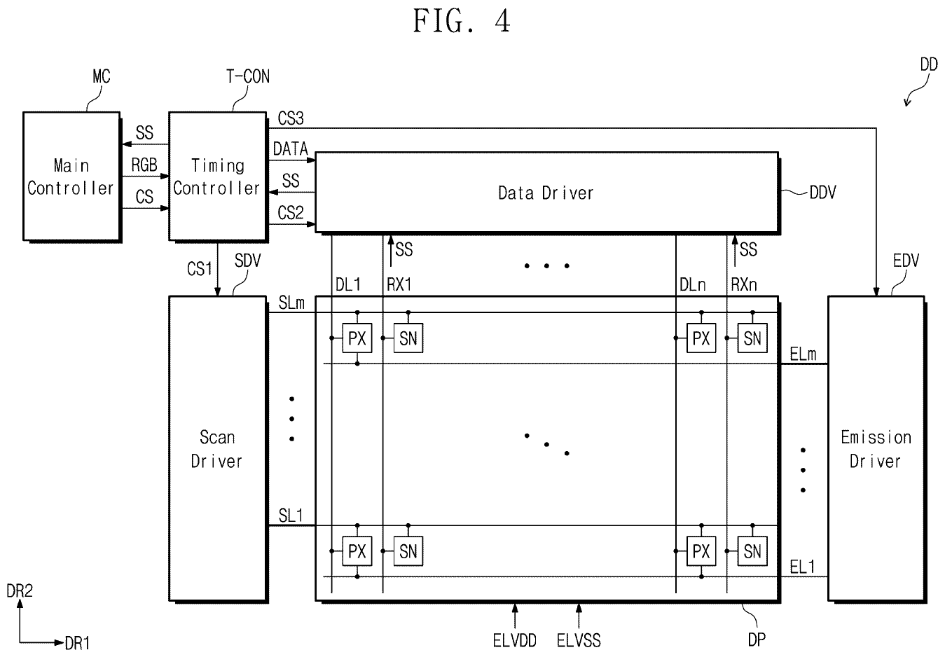

FIG. 3 is a diagram illustrating a cross section of the display panel illustrated in FIG. 2 as an example.

By way of example, FIG. 3 illustrates a cross section of the display panel DP viewed in the second direction DR2.

Referring to FIG. 3, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display region DA and a non-display region NDA around the display region DA. The substrate SUB may include glass or a flexible plastic material such as polyimide (PI). The display element layer DP-OLED may be disposed on the display region DA.

Multiple pixels may be disposed in the circuit element layer DP-CL and the display element layer DP-OLED. The pixels may each include a transistor disposed in the circuit element layer DP-CL and a light-emitting element disposed in the display element layer DP-OLED and connected to the transistor.

The thin-film encapsulation layer TFE may be disposed on the circuit element layer DP-CL to cover the display element layer DP-OLED. The thin-film encapsulation layer TFE may protect the pixels from moisture, oxygen and external foreign material.

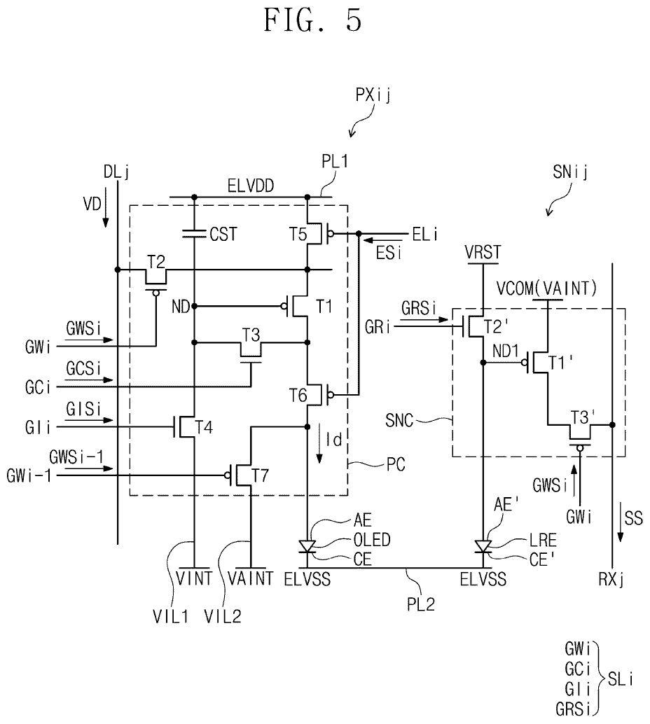

FIG. 4 is a block diagram of the display device illustrated in FIG. 1.

Referring to FIG. 4, the display device DD may include a display panel DP, a scan driver SDV, a data driver DDV, an emission driver EDV and a timing controller T-CON. The display panel DP may include multiple pixels PX, multiple sensors SN, multiple scan lines SL1 to SLm, multiple data lines DL1 to DLn, multiple emission lines EL1 to ELm and multiple reception lines RX1 to RXn, where m and n are natural numbers.

The scan lines SL1 to SLm may extend in the first direction DR1 and may be connected to the pixels PX and the scan driver SDV. The scan lines SL1 to SLm may be connected to the sensors SN. The data lines DL1 to DLn may extend in the second direction DR2 and may be connected to the pixels PX and the data driver DDV. The emission lines EL1 to ELm may extend in the first direction DR1 and may be connected to the pixels PX and the emission driver EDV. The reception lines RX1 to RXn may extend in the second direction DR2 and may be connected to the sensors SN and the data driver DDV.

A first voltage ELVDD and a second voltage ELVSS having a lower level than the first voltage ELVDD may be applied to the display panel DP. The first voltage ELVDD and the second voltage ELVSS may be applied to the pixels PX. The display device DD may further include a voltage generator for generating the first voltage ELVDD and the second voltage ELVSS.

The timing controller T-CON may receive image signals RGB and a control signal CS from a main controller MC (for example, a system board). The timing controller T-CON may convert data format of the image signals RGB and generate image data DATA to comply with specifications of interface with the data driver DDV. The timing controller T-CON may provide the data-format-converted image data DATA to the data driver DDV.

The timing controller T-CON may generate and output a first control signal CS1, a second control signal CS2 and a third control signal CS3 in response to the control signal CS provided from an exterior. The first control signal CS1 may be defined as a scan control signal, the second control signal CS2 may be defined as a data control signal, and the third control signal CS3 may be defined as an emission control signal. The first control signal CS1 may be provided to the scan driver SDV, the second control signal CS2 may be provided to the data driver DDV, and the third control signal CS3 may be provided to the emission driver EDV.

The scan driver SDV may generate multiple scan signals in response to the first control signal CS1. The scan signals may be applied to the pixels PX through the scan lines SL1 to SLm. The data driver DDV may generate multiple data voltages corresponding to the image data DATA in response to the second control signal CS2. The data voltages may be applied to the pixels PX through the data lines DL1 to DLn. The emission driver EDV may generate multiple emission signals in response to the third control signal CS3. The emission signals may be applied to the pixels PX through the emission lines EL1 to ELm.

The pixels PX may be provided with the data voltages in response to the scan signals. The pixels PX may display an image by emitting light in response to the emission signals of which a luminance corresponds to the data voltages in response to the emission signals. Emission time of the pixels PX may be controlled by the emission signals.

The sensors SN may sense a user's fingerprint and a user's touch pressure. For example, when a user touches the display device DD with a finger, the sensors SN may receive light reflected off the finger. The sensors SN may convert the received light into an electric signal and output the electric signal as a sensing signal SS.

The sensing signal SS may be provided to the data driver DDV through the reception lines. The sensing signal SS may be provided to the timing controller T-CON through the data driver DDV. The sensing signal SS may include information about a user's fingerprint and information about a user's touch pressure.

The timing controller T-CON may provide fingerprint information corresponding to sensing signals SS to the main controller MC. A user's fingerprint may be stored in the main controller MC. The main controller MC may compare a sensed fingerprint with the stored fingerprint of a user. Such an operation may occur in a user authentication mode. When the sensed fingerprint and the user's fingerprint match each other, a main controller MC may drive the display panel DP in a main mode according to control by the main controller MC. When the display panel DP is driven in the main mode, the user may normally use the display device DD.

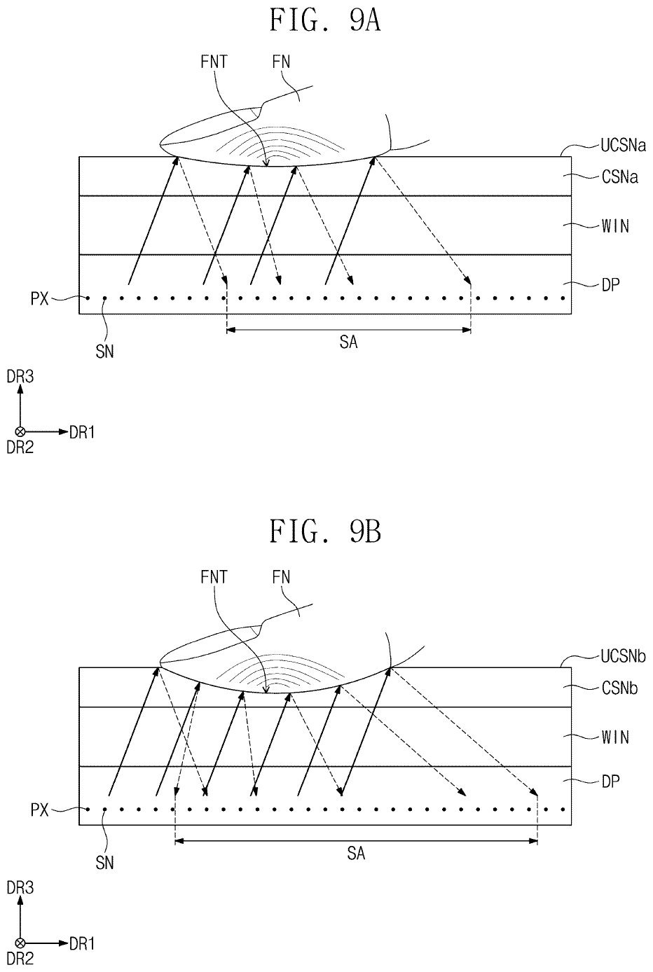

The timing controller T-CON may determine external pressure according to touch pressure information corresponding to the sensing signals SS. For example, the timing controller T-CON may determine external pressure exerted by a touch from the user according to a size of a sensing area and the amount of light received by the sensors SN. The timing controller T-CON may determine that the external pressure is greater when a size of a sensing area and the amount of light received by the sensors SN increases. The timing controller T-CON may determine that the external pressure is smaller when a size of a sensing area and an amount of light received by the sensors SN decreases. The size of the sensing area and the amount of light received by the sensors SN according to external pressure will be described in detail with reference to FIGS. 9A and 9B below.

The main controller MC may be provided with information about external pressure from the timing controller T-CON and control an operation of the display panel DP (see FIG. 2) according to the external pressure. For example, when a line is displayed on the display panel DP according to touch and movement of a user's finger, the main controller MC may control the display panel DP so that the line is thickly displayed when pressure is great and is thinly displayed when pressure is small.

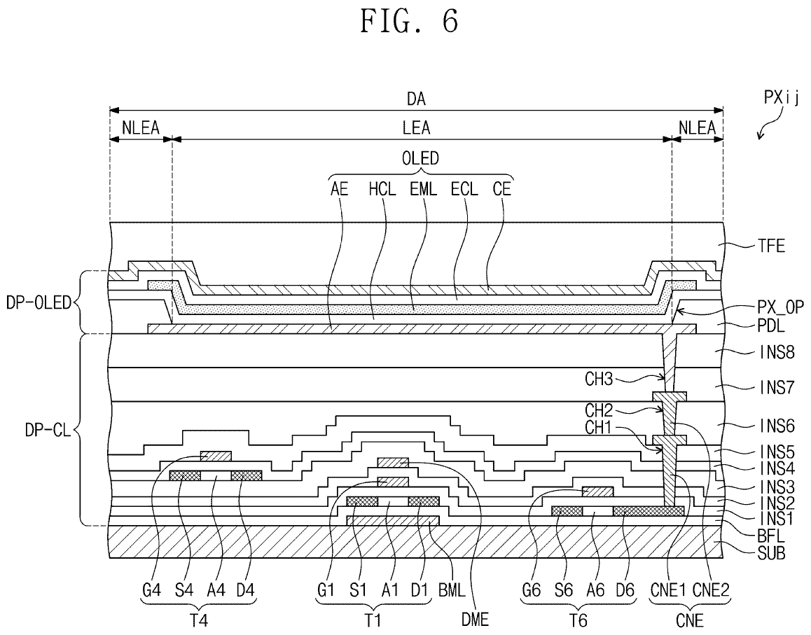

FIG. 5 is a diagram illustrating an equivalent circuit of a pixel among the pixels illustrated in FIG. 4 and a sensor adjacent to the pixel.

By way of example, FIG. 5 illustrates a pixel PXij connected to an i-th scan line SLi, an i-th emission line ELi and a j-th data line DLj. FIG. 5 illustrates a sensor SNij connected to an i-th reset line GRi and a j-th reception line RXj as an example, where i and j are natural numbers.

Referring to FIG. 5, the pixel PXij may include a pixel circuit PC and a light-emitting element OLED connected to the pixel circuit PC. The light-emitting element OLED may be disposed adjacent to a light-receiving element LRE. The pixel circuit PC may drive the light-emitting element OLED.

The pixel circuit PC may include multiple transistors T1 to T7 and a capacitor CST. The transistors T1 to T7 and the capacitor CST may control the amount of current flowing by the light-emitting element OLED. The light-emitting element OLED may generate light having a luminance according to the amount of provided current.

The i-th scan line SLi may include an i-th write scan line GWi, an i-th compensation scan line GCi and an i-th initialization scan line GIi. The i-th write scan line GWi may receive an i-th write scan signal GWSi, the i-th compensation scan line GCi may receive an i-th compensation scan signal GCSi, and the i-th initialization scan line GIi may receive an i-th initialization scan signal GISi.

Hereinafter, any one of a source electrode and a drain electrode of each of transistors disclosed herein may be referred to as a (1-1)-th electrode, and another thereof may be referred to as a (2-1)-th electrode. A gate electrode of each of the transistors may be referred to as a control electrode.

The transistors T1 to T7 may include first to seventh transistors T1 to T7. The first, second, fifth, sixth and seventh transistors T1, T2, T5, T6 and T7 may be PMOS transistors. The third and fourth transistors T3 and T4 may be NMOS transistors. The first to seventh transistors T1 to T7 may each include a source electrode, a drain electrode and a gate electrode.

The light-emitting element OLED may be defined as an organic light-emitting element. The light-emitting element OLED may include an anode AE and a cathode CE. The anode AE may receive a first voltage ELVDD through the sixth, first and fifth transistors T6, T1 and T5. The cathode CE may be connected to a second power line PL2 which receives a second voltage ELVSS.

The first transistor T1 may be connected between the fifth transistor T5 and the sixth transistor T6. The first transistor T1 may include a (1-1)-th electrode which receives the first voltage ELVDD through the fifth transistor T5, a (2-1)-th electrode connected to the anode AE through the sixth transistor T6 and a control electrode connected to a node ND.

The (1-1)-th electrode of the first transistor T1 may be connected to the fifth transistor T5, and the (2-1)-th electrode of the first transistor T1 may be connected to the sixth transistor T6. The first transistor T1 may control the amount of current flowing in the light-emitting element OLED according to a voltage of the node ND applied to the control electrode of the first transistor T1.

The second transistor T2 may be connected between the data line DLj and the (1-1)-th electrode of the first transistor T1. The second transistor T2 may include a (1-1)-th electrode connected to the data line DLj, a (2-1)-th electrode connected to the (1-1)-th electrode of the first transistor T1, and a control electrode connected to the i-th write scan line GWi.

The second transistor T2 may be turned on by the i-th write scan signal GWSi applied through the i-th write scan line GWi to electrically connect the data line DLj and the (1-1)-th electrode of the first transistor T1. The second transistor T2 may perform a switching operation by providing a data voltage VD applied through the data line DLj to the (1-1)-th electrode of the first transistor T1.

The third transistor T3 may be connected between the (2-1)-th electrode of the first transistor T1 and the node ND. The third transistor T3 may include a (1-1)-th electrode connected to the (2-1)-th electrode of the first transistor T1, a (2-1)-th electrode connected to the node ND, and a control electrode connected to the i-th compensation scan line GCi.

The third transistor T3 may be turned on by the i-th compensation scan signal GCSi applied through the i-th compensation scan line GCi and electrically connect the (2-1)-th electrode of the first transistor T1 and the control electrode of the first transistor T1. When the third transistor T3 is turned on, the first transistor T1 and the third transistor T3 may be diode-connected.

The fourth transistor T4 may be connected to the node ND. The fourth transistor T4 may include a (1-1)-th electrode connected to the node ND, a (2-1)-th electrode connected to a first initialization line VIL1, and a control electrode connected to the i-th initialization scan line GIi. The fourth transistor T4 may be turned on by the i-th initialization scan signal GISi applied through the i-th initialization scan line GIi to provide a first initialization voltage VINT applied through the first initialization line VIL1 to the node ND.

The fifth transistor T5 may include a (1-1)-th electrode connected to a first power line PL1 which receives the first voltage ELVDD, a (2-1)-th electrode connected to the (1-1)-th electrode of the first transistor T1, and a control electrode connected to the i-th emission line ELi.

The sixth transistor T6 may include a (1-1)-th electrode connected to the (2-1)-th electrode of the first transistor T1, a (2-1)-th electrode connected to the anode AE, and a control electrode connected to the i-th emission line ELi.

The fifth transistor T5 and the sixth transistor T6 may be turned on by an i-th emission signal ESi applied through the i-th emission line ELi. The first voltage ELVDD may be provided to the light-emitting element OLED through the turned-on fifth transistor T5 and sixth transistor T6, and thus driving current may flow in the light-emitting element OLED. Thus, the light-emitting element OLED may emit light.

The seventh transistor T7 may include an (1-1)-th electrode connected to the anode AE, a (2-1)-th electrode connected to a second initialization line VIL2, and a control electrode connected to an (i-1)-th write scan line GWi-1. The (i-1)-th write scan line GWi-1 may be defined as a write scan line of a previous stage of the i-th write scan line GWi.

The seventh transistor T7 may be turned on by an (i-1)-th write scan signal GWSi-1 applied through the (i-1)-th write scan line GWi-1 to provide a second initialization voltage VAINT to the anode AE of the light-emitting element OLED. The second initialization voltage VAINT may be received by the anode AE through the second initialization line VIL2.

In an embodiment of the disclosure, the second initialization voltage VAINT may have a different level from the first initialization voltage VINT but is not necessarily limited thereto and may have the same level as the first initialization voltage VINT.

The capacitor CST may include a (1-1)-th electrode which receives the first voltage ELVDD and a (2-1)-th electrode connected to the node ND. When the fifth transistor T5 and the sixth transistor T6 are turned on, the amount of current flowing in the first transistor T1 may be determined according to a voltage stored in the capacitor CST.

The display panel DP may include not only the pixel PXij but also the sensor SNij. The sensor SNij illustrated in FIG. 5 may be provided in plural to the display panel DP, thereby forming the sensing part described above.

The sensor SNij may include a sensing circuit SNC and the light-receiving element LRE connected to the sensing circuit SNC. The sensing circuit SNC may drive the light-receiving element LRE.

The sensing circuit SNC may include a first transistor T1′, a second transistor T2′ and a third transistor T3′. The first and third transistors T1′ and T3′ may be PMOS transistors, and the second transistor T2′ may be an NMOS transistor.

The first transistor T1′ may be connected to the light-receiving element LRE, the second transistor T2′ and the third transistor T3′. The first transistor T1′ may be connected to the light-receiving element LRE through a node ND1. The first transistor T1′ may include a (1-1)-th electrode which receives a voltage VCOM having a voltage level, a control electrode connected to the node ND1, and a (2-1)-th electrode connected to the third transistor T3′.

By way of example, the voltage VCOM may be set as the second initialization voltage VAINT but is not necessarily limited thereto and may be set as another voltage level.

The second transistor T2′ may include a (1-1)-th electrode connected to the node ND1, a control electrode connected to the i-th reset line GRi, and a (2-1)-th electrode connected to a reset voltage line VRL which receives a reset voltage VRST. An i-th reset signal GRSi received through the i-th reset line GRi may be applied to the control electrode of the second transistor T2′, and thus the second transistor T2′ may be turned on. The turned-on second transistor T2′ may receive and provide the reset voltage VRST to the node ND1. The node ND1 may be reset by the reset voltage VRST.

The third transistor T3′ may include a (1-1)-th electrode connected to the (2-1)-th electrode of the first transistor T1′, a control electrode connected to the i-th write scan line GWi, and a (2-1)-th electrode connected to the reception line RXj. The i-th write scan signal GWSi received through the i-th write scan line GWi may be applied to the control electrode of the third transistor T3′, and thus the third transistor T3′ may be turned on. The first transistor T1′ may be connected to the reception line RXj by the turned-on third transistor T3′.

The light-receiving element LRE may include a photodiode. An anode AE′ of the light-receiving element LRE may be connected to the node ND1, and a cathode CE′ of the light-receiving element LRE may be connected to the second power line PL2 which receives the second voltage ELVSS. The control electrode of the first transistor T1′ may be connected to the anode AE′ of the light-receiving element LRE through the node ND1. The light-receiving element LRE may convert light energy incident from an exterior into electric energy.

The light-receiving element LRE may receive and convert light into an electric signal, and in this case, a voltage of the node ND1 may change. When the first transistor T1′ is turned on, the voltage VCOM provided to the first transistor T1′ may be controlled according to a change in voltage of the node ND1 and be provided to the reception line RXj through the third transistor T3′. Thus, a signal generated by the light-receiving element LRE may be output as a sensing signal SS through the reception line RXj.

FIG. 5 illustrates a light-receiving element LRE as an example, but as long as the light-receiving element LRE may receive and convert light into an electric signal, the light-receiving element LRE may be in plural.

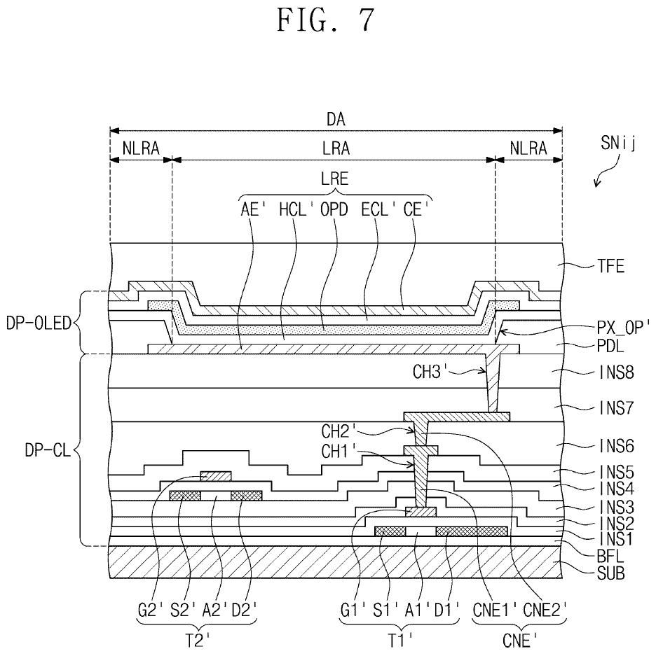

FIG. 6 is a diagram illustrating a cross section of the light-emitting element OLED, the first transistor T1, the fourth transistor T4 and the sixth transistor T6 of the pixel PXij illustrated in FIG. 5 as an example.

Referring to FIG. 6, the light-emitting element OLED may include a first electrode AE, a second electrode CE, a hole control layer HCL, an electron control layer ECL and an emission layer EML. FIG. 6 illustrates a light-emitting element OLED, but the light-emitting element OLED may be in plural. The first electrode AE may be the anode AE illustrated in FIG. 5, and the second electrode CE may be the cathode CE illustrated in FIG. 5. The second electrode CE may be disposed on the first electrode AE, and the hole control layer HCL, the electron control layer ECL and the emission layer EML may be disposed between the first electrode AE and the second electrode CE.

The first, fourth and sixth transistors T1, T4 and T6 and the light-emitting element OLED may be disposed on a substrate SUB. A display region DA may include a light-emitting region LEA corresponding to the pixel PXij and a non-light-emitting region NLEA adjacent to the light-emitting region LEA. The light-emitting element OLED may be disposed in the light-emitting region LEA.

A lower metal layer BML may be disposed on the substrate SUB. The lower metal layer BML may overlap the first transistor T1. The lower metal layer BML may receive a constant voltage. When the constant voltage is applied to the lower metal layer BML, a value of a threshold voltage Vth of the first transistor T1 disposed on the lower metal layer BML may be maintained without being changed.

The lower metal layer BML may block light incident from below the lower metal layer BML to the first transistor T1. The lower metal layer BML may include reflective metal. The lower metal layer BML may be omitted.

A buffer layer BFL may be disposed on the substrate SUB, and the buffer layer BFL may be an inorganic layer. The buffer layer BFL may cover the lower metal layer BML. A semiconductor layer S1, A1 and D1 of the first transistor T1 and a semiconductor layer S6, A6 and D6 of the sixth transistor T6 may be disposed on the buffer layer BFL. The semiconductor layers S1, A1, D1, S6, A6 and D6 may include polysilicon. However, an embodiment of the disclosure is not necessarily limited thereto, and the semiconductor layers S1, A1, D1, S6, A6 and D6 may include amorphous silicon.

The semiconductor layers S1, A1, D1, S6, A6 and D6 may be doped with an N-type dopant or a P-type dopant. The semiconductor layers S1, A1, D1, S6, A6 and D6 may include a heavily doped region and a lightly doped region. The heavily doped region may have higher conductivity than the lightly doped region and may substantially serve as a source electrode and a drain electrode of the first and sixth transistors T1 and T6. The lightly doped region may substantially correspond to an active region (or a channel) of the first and sixth transistors T1 and T6.

A first source region S1, a first channel region A1 and a first drain region D1 of the first transistor T1 may be formed from the semiconductor layer S1, A1 and D1. A sixth source region S6, a sixth channel region A6 and a sixth drain region D6 of the sixth transistor T6 may be formed from the semiconductor layer S6, A6 and D6. The first channel region A1 may be disposed between the first source region S1 and the first drain region D1. The sixth channel region A6 may be disposed between the sixth source region S6 and the sixth drain region D6.

A first insulating layer INS1 may be disposed on the buffer layer BFL to cover the semiconductor layers S1, A1, D1, S6, A6 and D6. First and sixth gate electrodes G1 and G6 (or control electrodes) of the first and sixth transistors T1 and T6, respectively, may be disposed on the first insulating layer INS1.

A structure of a source region, a channel region, a drain region and a gate electrode of each of the second, fifth and seventh transistors T2, T5 and T7 may be substantially the same as those of the first and sixth transistors T1 and T6.

A second insulating layer INS2 may be disposed on the first insulating layer INS1 to cover the first and sixth gate electrodes G1 and G6. A dummy electrode DME may be disposed on the second insulating layer INS2. The dummy electrode DME may be disposed on the first gate electrode G1 and overlap the first gate electrode G1 in a plan view. The dummy electrode DME may form the capacitor CST described above together with the first gate electrode G1.

A third insulating layer INS3 may be disposed on the second insulating layer INS2 to cover the dummy electrode DME. A semiconductor layer S4, A4 and D4 of the fourth transistor T4 may be disposed on the third insulating layer INS3. The semiconductor layer S4, A4 and D4 may include oxide semiconductor formed of metal oxide. The oxide semiconductor may include crystalline or amorphous oxide semiconductor.

The semiconductor layer S4, A4 and D4 may include multiple regions which are divided according to whether metal oxide is reduced or not. A region in which metal oxide is reduced (hereinafter, a reduced region) has higher conductivity than a region in which metal oxide is not reduced (hereinafter, a non-reduced region). The reduced region may substantially serve as a source electrode or a drain electrode of the fourth transistor T4. The non-reduced region may substantially correspond to an active region (or a channel) of the fourth transistor T4.

A fourth source region S4, a fourth channel region A4 and a fourth drain region D4 of the fourth transistor T4 may be formed from the semiconductor layer S4, A4 and D4. The fourth channel region A4 may be disposed between the fourth source region S4 and the fourth drain region D4.

A fourth insulating layer INS4 may be disposed on the third insulating layer INS3 to cover the semiconductor layer S4, A4 and D4. A fourth gate electrode G4 of the fourth transistor T4 may be disposed on the fourth insulating layer INS4.

A fifth insulating layer INS5 may be disposed on the fourth insulating layer INS4 to cover the fourth gate electrode G4. A structure of a source region, a channel region, a drain region and a gate electrode of the third transistor T3 may be substantially the same as that of the fourth transistor T4.

The buffer layer BFL and the first to fifth insulating layers INS1 to INS5 may include inorganic layers. By way of example, the buffer layer BFL, the first insulating layer INS1 and the fourth insulating layer INS4 may include a silicon oxide layer, and the second insulating layer INS2 may include a silicon nitride layer.

The third and fifth insulating layers INS3 and INS5 may include multiple inorganic insulating layers including different materials from each other and stacked on each other. For example, the third insulating layer INS3 may include a silicon nitride layer and a silicon oxide layer which are sequentially stacked on each other, and the fifth insulating layer INS5 may include a silicon oxide layer and a silicon nitride layer which are sequentially stacked on each other. A thickness of each of the third and fifth insulating layers INS3 and INS5 may be greater than a thickness of each of the buffer layer BFL and the first, second and fourth insulating layers INS1, INS2 and INS4.

A connection electrode CNE may be disposed between the sixth transistor T6 and the light-emitting element OLED. The connection electrode CNE may electrically connect the sixth transistor T6 and the light-emitting element OLED. The connection electrode CNE may include a first sub-connection electrode CNE1 and a second sub-connection electrode CNE2 disposed on the first sub-connection electrode CNE1.

The first sub-connection electrode CNE1 may be disposed on the fifth insulating layer INS5 and be connected to the sixth drain region D6 via a first contact hole CH1 defined in the first to fifth insulating layers INS1 to INS5. A sixth insulating layer INS6 may be disposed on the fifth insulating layer INS5 to cover the first sub-connection electrode CNE1.

The second sub-connection electrode CNE2 may be disposed on the sixth insulating layer INS6. The second sub-connection electrode CNE2 may be connected to the first sub-connection electrode CNE1 via a second contact hole CH2 defined in the sixth insulating layer INS6.

A seventh insulating layer INS7 may be disposed on the sixth insulating layer INS6 to cover the second sub-connection electrode CNE2, and an eighth insulating layer INS8 may be disposed on the seventh insulating layer INS7. The sixth to eighth insulating layers INS6 to INS8 may include an inorganic layer or an organic layer.

The first electrode AE may be disposed on the eighth insulating layer INS8. The first electrode AE may be electrically connected to the second sub-connection electrode CNE2 via a third contact hole CH3 defined in the seventh and eighth insulating layers INS7 and INS8.

A pixel-defining film PDL which exposes a portion of the first electrode AE may be disposed on the first electrode AE and the eighth insulating layer INS8. An opening PX_OP for exposing the portion of the first electrode AE may be defined in the pixel-defining film PDL.

The hole control layer HCL may be disposed on the first electrode AE and the pixel-defining film PDL. The hole control layer HCL may be disposed in the light-emitting region LEA and the non-light-emitting region NLEA in common. The hole control layer HCL may include a hole transport layer and a hole injection layer.

The emission layer EML may be disposed on the hole control layer HCL. The emission layer EML may be disposed in a region corresponding to the opening PX_OP. The emission layer EML may include an organic material and/or an inorganic material. The emission layer EML may generate light typically including any one of red, green and blue.

The electron control layer ECL may be disposed on the emission layer EML and the hole control layer HCL. The electron control layer ECL may be disposed in the light-emitting region LEA and the non-light-emitting region NLEA in common. The electron control layer ECL may include an electron transport layer and an electron injection layer.

The second electrode CE may be disposed on the electron control layer ECL. The second electrode CE may be disposed in common in the pixels PX. For example, the second electrode CE may be disposed in common on emission layers EML of the pixels PX.

Layers from the buffer layer BFL up to the eighth insulating layer INS8 may be defined as a circuit element layer DP-CL. A layer in which the light-emitting element OLED is disposed may be defined as a display element layer DP-OLED.

A thin-film encapsulation layer TFE may be disposed on the light-emitting element OLED. The thin-film encapsulation layer TFE may include an inorganic layer, an organic layer and an inorganic layer which are sequentially stacked on each other. The inorganic layers may include an inorganic material and protect the pixels from moisture/oxygen. The organic layer may include an organic material and protect the pixels PX from foreign material such as dust particles.

The first voltage ELVDD may be applied to the first electrode AE, and the second voltage ELVSS may be applied to the second electrode CE. Holes and electrons injected to the emission layer EML may combine with each other to form excitons, and as the excitons transition to a ground state, the light-emitting element OLED may emit light, and thus an image may be displayed.

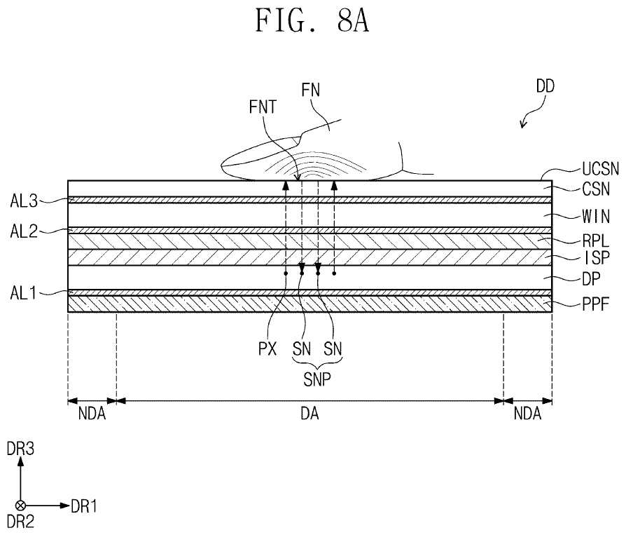

FIG. 7 is a diagram illustrating a cross section of the light-receiving element LRE, the first transistor T1′ and the second transistor T2′ of the sensor illustrated in FIG. 5 as an example.

Hereinafter, a configuration illustrated in FIG. 7 will be described mainly focusing on a structure different from the stack structure illustrated in FIG. 6.

Referring to FIG. 7, a display region DA may include a light-receiving region LRA corresponding to the sensor SNij and a non-light-receiving region NLRA adjacent to the light-receiving region LRA. The non-light-receiving region NLRA may be the non-light-receiving region NLRA illustrated in FIG. 7.

FIG. 7 illustrates a sensor SNij, but the sensor SNij may be in plural. The sensor SNij may be disposed on a substrate SUB and include the light-receiving element LRE.

The light-receiving element LRE may include a first electrode AE′, a second electrode CE′, a hole control layer HCL′, an electron control layer ECL′ and a light-receiving layer OPD. The first electrode AE′ may be the anode AE′ illustrated in FIG. 5, and the second electrode CE′ may be the cathode CE′ illustrated in FIG. 5.

The light-receiving layer OPD may be defined as an organic photodiode. The first electrode AE′, the second electrode CE′, the hole control layer HCL′ and the electron control layer ECL′ may be substantially the same components as the first electrode AE, the second electrode CE, the hole control layer HCL and the electron control layer ECL, respectively, illustrated in FIG. 6.

A position at which the light-receiving layer OPD is disposed in FIG. 7 may correspond to a position at which the emission layer EML is disposed in FIG. 6. For example, the second electrode CE′ may be disposed on the first electrode AE′, and the hole control layer HCL′, the electron control layer ECL′ and the light-receiving layer OPD may be disposed between the first electrode AE′ and the second electrode CE′. The second electrode CE′ may be disposed in common on light-receiving layers OPD of light-receiving elements LRE. The second electrode CE′ and the second electrode CE illustrated in FIG. 5 may be a single, uninterrupted structure.

The first transistor T1′ may include a first source region S1′, a first drain region D1′, a first channel region A1′ and a first gate electrode G1′. The second transistor T2′ may include a second source region S2′, a second drain region D2′, a second channel region A2′ and a second gate electrode G2′.

A stack structure of the first transistor T1′ may be substantially the same as a stack structure of the first transistor T1 illustrated in FIG. 6. A stack structure of the second transistor T2′ may be substantially the same as a stack structure of the fourth transistor T4 illustrated in FIG. 6. A stack structure of the third transistor T3′ may be substantially the same as the stack structure of the first transistor T1′.

A connection electrode CNE′ may include a first sub-connection electrode CNE1′ and a second sub-connection electrode CNE2′. The first sub-connection electrode CNE1′ and the first sub-connection electrode CNE1 illustrated in FIG. 6 may be disposed in (i.e., “formed from”) a same layer, and the second sub-connection electrode CNE2′ and the second sub-connection electrode CNE2 illustrated in FIG. 6 may be disposed in (i.e., “formed from”) a same layer. Thus, the first sub-connection electrode CNE1′ may be disposed on the fifth insulating layer INS5, and the second sub-connection electrode CNE2′ may be disposed on the sixth insulating layer INS6.

The first sub-connection electrode CNE1′ may be connected to the first gate electrode G1′ of the first transistor T1′ via a first contact hole CH1′ defined in second to fifth insulating layers INS2 to INS5. The second sub-connection electrode CNE2′ may be connected to the first sub-connection electrode CNE1′ via a second contact hole CH2′ defined in the sixth insulating layer INS6. The first electrode AE′ of the light-receiving element LRE may be connected to the second sub-connection electrode CNE2′ via a third contact hole CH3′ defined in seventh and eighth insulating layers INS7 and INS8.

A shielding electrode may be disposed on the seventh insulating layer INS7. The shielding electrode and the third contact hole CH3′ may be spaced apart from each other. The eighth insulating layer INS8 may be disposed on the seventh insulating layer INS7 to cover the shielding electrode.

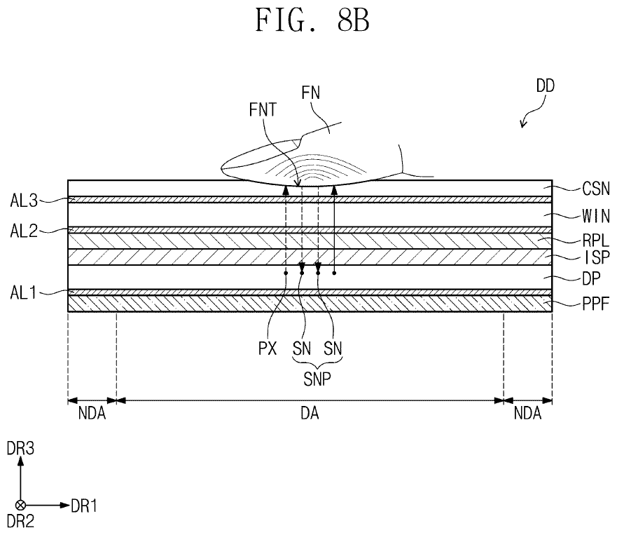

FIG. 8A is a diagram illustrating a state in which a fingerprint is sensed by the sensors illustrated in FIGS. 5 and 7 as an example.

Referring to FIGS. 5, 6, 7 and 8A, a display device DD may include a cushion layer CSN and a sensing part SNP embedded in a display panel DP, and the sensing part SNP may include multiple sensors SN. The cushion layer CSN may include a transparent polymer and a transparent urethane material. The sensors SN may each have a configuration like that of the sensor SNij illustrated in FIGS. 5 and 7. By way of example, FIG. 8A illustrates two sensors SN, but substantially more sensors SN may be disposed in the display panel DP and constitute the sensing part SNP.

An external object (for example, a finger FN of a user) may be provided onto the cushion layer CSN. Hereinafter, the external object is described as the finger FN for convenience. The sensors SN may sense a fingerprint FNT of the finger FN provided onto the display panel DP. Light generated by light-emitting elements OLED of the pixels PX may be incident onto the fingerprint FNT may reflect off the fingerprint FNT. For convenience of description, FIG. 8A illustrates an upper surface of the cushion layer CSN in a substantially flat state without being deformed to illustrate a state in which a fingerprint is sensed. However, an upper surface UCSN of the cushion layer CSN may deform substantially according to pressure exerted by the finger, and the deformed state is illustrated in FIG. 8B.

The light reflected off the fingerprint FNT may be sensed by light-receiving elements LRE of the sensors SN. The sensors SN may sense the fingerprint FNT through the light reflected off the fingerprint FNT. Information about the fingerprint sensed by the sensors SN may be received, and the user authentication mode described above may be performed using the received fingerprint information.

FIG. 8B is a diagram illustrating a state in which pressure is sensed by the sensors illustrated in FIGS. 5 and 7 as an example.

Referring to FIGS. 5, 6, 7 and 8B, the sensors SN may sense external pressure applied to the cushion layer CSN by the finger FN in contact with the display panel DP.

The finger FN may exert pressure (for example, external pressure) onto the cushion layer CSN. For example, the finger FN may be in direct contact with the cushion layer CSN and may press the cushion layer CSN in a direction opposite to the third direction DR3. The cushion layer CSN may deform according to pressure exerted by the finger.

Light generated by the light-emitting elements OLED of the pixels PX may impinge onto the finger FN. The light incident onto the finger FN may reflect off the finger FN. The sensors SN may sense the light reflected off the finger FN. The external pressure may be sensed through a sensing signal SS generated by the sensors SN.

The amount of light reflected and a size of the sensing area may vary according to pressure. The external pressure may be determined in the timing controller T-CON (see FIG. 4) according to the amount of light reflected and the size of the sensing area. Such a state will be described with reference to FIGS. 9A and 9B below.

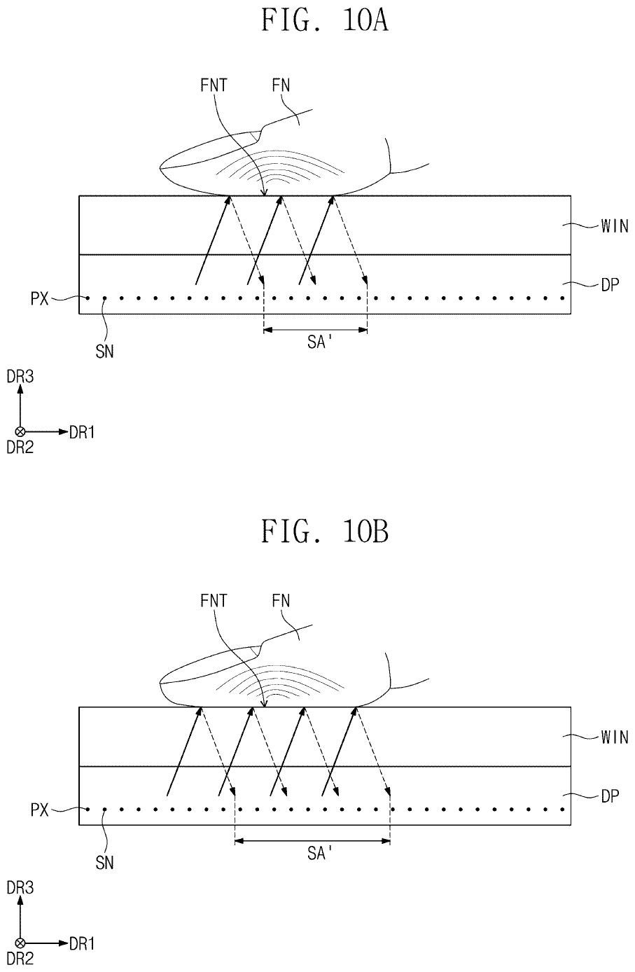

The timing controller T-CON may determine the external pressure according to touch pressure information corresponding to sensing signals. For example, the timing controller T-CON may determine external pressure exerted by a touch from the user according to a size of a sensing area and the amount of light received by the sensors SN. The timing controller T-CON may determine that the external pressure increases when a size of a sensing area and the amount of light received by the sensors SN increase. The timing controller T-CON may determine that the external pressure decreases when a size of a sensing area and the amount of light received by the sensors SN decreases. A size of the sensing area and the amount of light received by the sensors SN according to external pressure will be described in detail with reference to FIGS. 9A to 10B below.

FIGS. 9A and 9B are cross-sectional views illustrating in more detail a state in which pressure is sensed by the sensors illustrated in FIG. 7.

FIGS. 9A and 9B each illustrate a configuration of a cushion layer CSNa or CSNb, a window WIN, and a display panel DP for convenience of description.

Referring to FIGS. 4, 9A and 9B and as described above, light generated by the pixels PX may be incident onto a finger FN, and the sensors SN may receive and sense light reflected off the finger FN. For example, the light-receiving elements LRE of the sensors SN described above may sense the reflected light. The amount of light reflected off the finger FN may vary according to external pressure.

The light reflected off the finger FN may be received in the sensors SN, the amount of received light may vary according to a change in the amount of reflected light, and an a size of an area in which light is received by the sensors SN may vary according to a change in the amount of light. For example, a size of a sensing area SA of the sensors SN may vary. The timing controller T-CON may determine external pressure exerted by the finger FN according to sensing signals SS received from the sensors SN pertaining to a size of the sensing area SA and the amount of light received by the sensors SN.

FIG. 9A illustrates an example of a sensing state according to small external pressure, and FIG. 9B illustrates an example of a sensing state according to a larger external pressure.

Referring to FIG. 9A, when external pressure decreases, a displacement of the cushion layer CSNa deformed in a direction opposite to the third direction DR3 may decrease. For example, as the external pressure decreases, the amount of deformation in the cushion layer CSNa may decrease.

As the external pressure decreases, a contact area of the finger FN with respect to the cushion layer CSNa may decrease. Light generated by the pixels PX may reflect off of a portion of the finger FN in contact with an upper surface UCSNa of the cushion layer CSNa.

Since a contact area of the finger FN with respect to the cushion layer CSNa decreases as the amount of deformation in the cushion layer CSNa decreases, the amount of light reflected off the finger FN may decrease. A size of an area in which the sensors SN receive light reflected off of the finger FN of the display panel DP may be defined as the sensing area SA.

When a contact area of the finger FN with respect to the cushion layer CSNa decreases, the size of the sensing area SA of the display panel DP that receives light reflected off of the finger FN may also decrease. Thus, as the amount of deformation in the cushion layer CSNa decreases and the number of the sensors SN which receive the light reflected off of the finger FN may decrease, and therefore the size of the sensing area SA of the display panel DP may also decrease. In this case, the timing controller T-CON may determine that the external pressure is smaller as the size of the sensing area SA and the amount of light received by the sensors SN become smaller.

Referring to FIG. 9B, when external pressure increases, a displacement of the cushion layer CSNb deformed in a direction opposite to the third direction DR3 may increase. For example, as the external pressure increases, the amount of deformation in the cushion layer CSNb may increase.

As the external pressure increases, a contact area of the finger FN with respect to the cushion layer CSNb may increase. Light generated by the pixels PX may reflect off of a portion of the finger FN in contact with an upper surface UCSNb of the cushion layer CSNb.

Since a contact area of the finger FN with respect to the cushion layer CSNb increases as the amount of deformation in the cushion layer CSNb increases, the amount of light reflected off the finger FN may increase.

When a contact area of the finger FN with respect to the cushion layer CSNb increases, the size of the sensing area SA of the display panel DP receiving light reflected off the finger FN may also increase. Thus, as the amount of deformation in the cushion layer CSNb increases, the number of the sensors SN which receive light reflected off of the finger FN may increase. The size of the sensing area SA of the display panel DP may also increase. In this case, the timing controller T-CON may determine that the external pressure has increased as the size of the sensing area SA and the amount of light received by the sensors SN increase.

An angle between light incident on the finger FN from the pixels PX and light reflected off the finger FN and received by the sensors SN may be about 71° or less. A length, in the first direction DR1 of a portion in which the finger FN is in direct contact with the upper surface UCSNa or UCSNb of the cushion layer CSNa or CSNb may be about 65 μm or less, and maximum external pressure that the cushion layer CSNa or CSNb receives from the finger FN may be about 70 gf/mm². An angle between light incident onto and light reflected from the finger FN may be about 71° or less when the cushion layer CSNa or CSNb is deformed due to external pressure.

FIGS. 10A and 10B are cross-sectional views illustrating in mor detail a state in which pressure is sensed by the sensors illustrated in FIG. 7.

FIGS. 10A and 10B illustrate a state in which pressure is sensed when the cushion layer CSN (see FIG. 8A) is removed in an embodiment of the disclosure.

Referring to FIGS. 4, 10A and 10B, as described above, light generated by the pixels PX may be incident onto a finger FN, and sensors SN may receive and sense light reflected off the finger FN.

FIG. 10A illustrates a state in which a size of an area in which the finger FN is in contact with the window WIN is small, and FIG. 10B illustrates a state in which a size of an area in which the finger FN is in contact with the window WIN is large.

As external pressure decreases, an area in which the finger FN is in contact with the window WIN may decrease. The light generated by the pixels PX may reflect off of a portion of the finger FN that is in contact with the window WIN.

When an area in which the finger FN that is in contact with the window WIN decreases, the amount of light reflected off the finger FN may decrease. A size of a sensing area SA′ of the display panel DP receiving the light reflected off the finger FN may also decrease. Thus, as a size of an area in which the finger FN is in contact with the window WIN decreases, the number of sensors SN which receive light reflected off the finger FN may decrease. The size of the sensing area SA′ of the display panel DP may also decrease. In this case, the timing controller T-CON may determine that the external pressure decreases as the size of the sensing area SA′ and the amount of light received by the sensors SN decreases.

As external pressure increases, a size of an area in which the finger FN is in contact with the window WIN may increase. In this case, the amount of light reflected off the finger FN may increase. The size of the sensing area SA′ of the display panel DP that receives light reflected off the finger FN may also increase. Thus, as a size of an area in which the finger FN is in contact with the window WIN increases, the number of the sensors SN which receive light reflected off the finger FN may increase so that the size of the sensing area SA′ of the display panel DP may also increase. In this case, the timing controller T-CON may determine that the external pressure has increased because the size of the sensing area SA′ and the amount of light received by the sensors SN has increased.

According to embodiments of the disclosure, there is provided a design for a display device and an electronic device that includes the same that indirectly senses external pressure of a user's finger on a display surface of the device. Sensors are embedded in the display panel that directly sense an amount of light originating from the pixels that reflects off of the finger, and also senses a size of a sensing area corresponding to sensors that receive light reflected off of the finger. The sensors produce sensing signals pertain to the amount of light reflected and a size of the sensing area to a timing controller to determine the pressure of the finger on the front of the display panel.

The display device may or may not include a cushion layer CSN on the window WIN. Advantages of the cushion layer CSN include varying amount of deformation for varying amounts of exerted pressure. Thus if more pressure is exerted, more deformation of the cushion layer occurs, resulting in more reflected light reaching the sensors and a greater sensing area to facilitate sensing a pressure exerted by a user's finger.

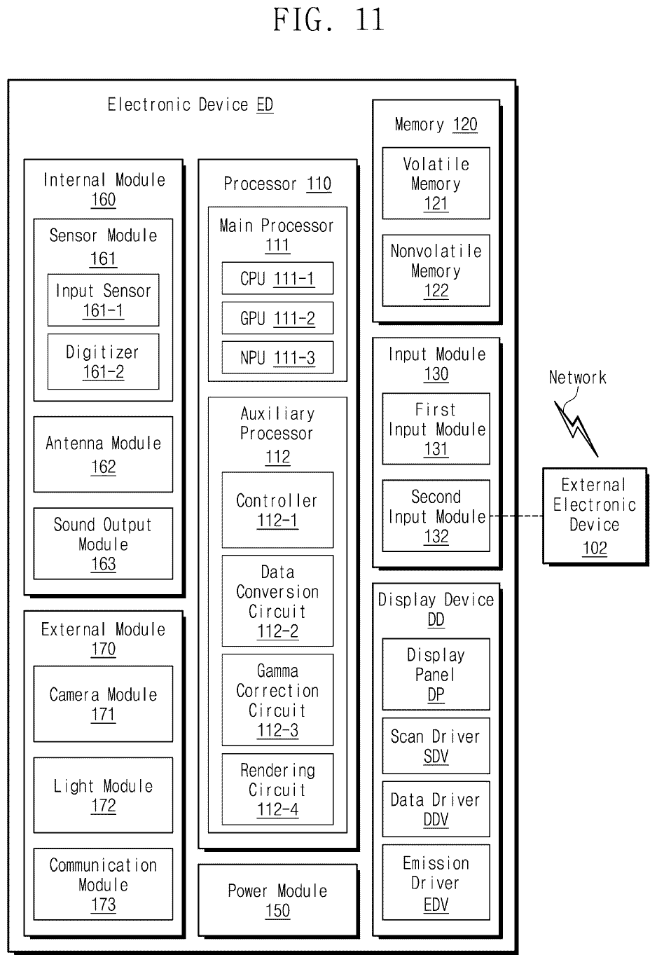

FIG. 11 is a block diagram of an electronic device according to embodiments of the disclosure.

Referring to FIG. 11, an electronic device ED may output a variety of information through a display device DD in an operating system. When a processor 110 executes an application stored in a memory 120, the display device DD may provide application information to a user through a display panel DP.

The processor 110 obtains an external input through an input module 130 or a sensor module 161 and executes an application corresponding to the external input. For example, when a user selects a camera icon displayed on the display panel DP, the processor 110 may obtain a user input through an input sensor 161-1 and activate a camera module 171. The processor 110 may transmit to the display device DD image data corresponding to a an image captured by the camera module 171. The display device DD may display an image corresponding to the captured image through the display panel DP.

For another example, when a music streaming icon displayed on the display device DD is selected, the processor 110 may obtain a user input through the input sensor 161-1 and activate a music streaming application stored in the memory 120. When a music execution command is input in the music streaming application, the processor 110 may activate a sound output module 163 and provide sound information that complies with the music execution command to a user.

An operation of the electronic device ED is briefly described above. Hereinafter, a configuration of the electronic device ED is described in detail. Some of components of the electronic device ED to be described later may be integrated and provided as one (e.g., “a single”) component, and one (e.g., “a single”) component may be separated into two or more components and provided.

The electronic device ED may communicate with an external electronic device 102 via a network (for example, a short-range wireless communication network or a long-range wireless communication network). According to an embodiment, the electronic device ED may include the processor 110, the memory 120, the input module 130, the display device DD, a power module 150, an internal module 160, and an external module 170. According to an embodiment, at least one of the components described above may be omitted from the electronic device ED, or one or more other components may be added to the electronic device ED. According to an embodiment, some (for example, the sensor module 161, an antenna module 162 or the sound output module 163) of the components described above may be integrated with another component (for example, the display device DD).

The processor 110 may execute software and control at least one other component (for example, a hardware or software component), which are connected to the processor 110 of the electronic device ED, and may perform a variety of data processing or other operations. According to an embodiment, in the data processing or other operations, the processor 110 may store data or a command received from another component (for example, the input module 130, the sensor module 161 or a communication module 173) in a volatile memory 121 and process the data or command stored in the volatile memory 121, and resultant data may be stored in a nonvolatile memory 122.

The processor 110 may include a main processor 111 and an auxiliary processor 112. The main processor 111 may include one or more among a central processing unit (CPU) 111-1 and an application processor (AP). The main processor 111 may further include one or more among a graphic processing unit (GPU) 111-2, a communication processor (CP) and an image signal processor (ISP).

The main processor 111 may further include a neural processing unit (NPU) 111-3. The neural processing unit may be a processor specialized for processing an artificial intelligence model, and the artificial intelligence model may be generated through machine learning. The artificial intelligence model may include multiple artificial neural network layers.

An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, or a combination thereof, but is not necessarily limited to the examples described above.

The artificial intelligence model may include a software structure in addition to or instead of a hardware structure. At least two among the processing units and the processors described above may be implemented as an integrated component (for example, a single chip) or may be respectively implemented as independent components (for example, multiple chips).

The auxiliary processor 112 may include a controller 112-1. The controller 112-1 may include an interface conversion circuit and a timing control circuit. The controller 112-1 may receive an image signal from the main processor 111 and convert data format of the image signal to comply with specifications of interface with the display device DD and output image data. The controller 112-1 may output various types of control signals required for driving the display device DD.

The auxiliary processor 112 may further include a data conversion circuit 112-2, a gamma correction circuit 112-3, a rendering circuit 112-4, etc. The data conversion circuit 112-2 may receive image data from the controller 112-1 and compensate the image data so that an image is displayed at a desired luminance according to characteristics of the electronic device ED, a user's setting, or the like, or convert the image data to reduce power consumption, to compensate an afterimage, or the like.

The gamma correction circuit 112-3 may convert image data, a gamma reference voltage, or the like so that an image displayed on the electronic device ED has a desired gamma characteristic.

The rendering circuit 112-4 may receive image data from the controller 112-1 and render the image data in consideration of pixel arrangement of the display panel DP applied to the electronic device ED, etc.

At least one of the data conversion circuit 112-2, the gamma correction circuit 112-3, or the rendering circuit 112-4 may be integrated with another component (for example, the main processor 111 or the controller 112-1). At least one of the data conversion circuit 112-2, the gamma correction circuit 112-3, or the rendering circuit 112-4 may be integrated with a data driver DDV to be described later.

The memory 120 may store various pieces of data used by at least one component (for example, the processor 110 or the sensor module 161) of the electronic device ED, and output data or input data about a command related thereto. The memory 120 may include at least one of the volatile memory 121 or the nonvolatile memory 122.

The input module 130 may receive data or a command that is used in a component (for example, the processor 110, the sensor module 161 or the sound output module 163) of the electronic device ED from an exterior (for example, a user or the external electronic device 102) of the electronic device ED.

The input module 130 may include a first input module 131 to which a command or data is input from a user and a second input module 132 to which a command or data is input from the external electronic device 102. The first input module 131 may include a microphone, a mouse, a keyboard, a key (for example, a button) or a pen (for example, a passive pen or an active pen).

The second input module 132 may support a designated protocol for wired or wireless connection to the external electronic device 102. According to an embodiment, the second input module 132 may include a high definition multimedia interface (HDMI), a universal serial bus (USB) interface, an SD card interface, or an audio interface. The second input module 132 may include a connector for physical connection to the external electronic device 102, for example, an HDMI connector, a USB connector, an SD card connector, or an audio connector (for example, a headphone connector).

The display device DD may visually provide information to a user. As described with reference to FIG. 4, the display device DD may include the display panel DP, a scan driver SDV, an emission driver EDV and the data driver DDV. The display device DD may further include a chassis, a bracket, and a window for protecting the display panel DP.

The display panel DP may include a liquid crystal display panel, an organic light-emitting display panel or an inorganic light-emitting display panel, and a type of the display panel DP is not necessarily limited. The display panel DP may be a rigid-type display panel or a flexible-type display panel that is rollable or foldable. The display device DD may further include a supporter that supports the display panel DP, a bracket, a heat dissipation member, or the like.

The display device DD may further include a voltage generation circuit. The voltage generation circuit may output various types of voltages required for driving the display panel DP.

The power module 150 may supply power to a component of the electronic device ED. The power module 150 may include a battery which charges a power voltage. The battery may include a non-rechargeable primary cell, a rechargeable secondary cell, or a fuel cell. The power module 150 may include a power management integrated circuit (PMIC). The PMIC may supply optimized power to each of modules and the display device DD. The power module 150 may include a wireless power transmission/reception member electrically connected to the battery. The wireless power transmission/reception member may include multiple antenna radiators in a coil form.

The electronic device ED may further include the internal module 160 and the external module 170. The internal module 160 may include the sensor module 161, the antenna module 162 and the sound output module 163. The external module 170 may include the camera module 171, a light module 172 and the communication module 173.

The sensor module 161 may sense an input from a user's body or an input from a pen of the first input module 131 and generate a data value or an electric signal corresponding to the input. The sensor module 161 may include at least one of the input sensor 161-1 or a digitizer 161-2.

The input sensor 161-1 may generate a data value corresponding to coordinate information about an input from a user's body or an input from a pen. The input sensor 161-1 may generate the amount of deformation in capacitance due to the input as a data value. As discussed previously in conjunction with FIGS. 4 to 10B, the input sensor 161-1 correspond to sensing part SNP that includes sensors SN that generate sensing signals SS pertaining to an amount of pressure exerted by a user's finger and a size of a sensing area to determine pressure exerted by a finger FN. The input sensor 161-1 may sense an input from a passive pen or transmit/receive data to/from an active pen.

The input sensor 161-1 may measure a biosignal such as blood pressure, water or body fat. For example, when a user is in contact with a sensor layer or a sensing panel with a part of a user's body and does not move for a certain amount of time, on the basis of a change in electric field caused by the part of the user's body, the input sensor 161-1 may sense a biosignal and output information desired by the user to the display device DD.

The digitizer 161-2 may generate a data value corresponding to coordinate information about an input from a pen. The digitizer 161-2 may generate the amount of electromagnetic change due to the input as a data value. The digitizer 161-2 may sense an input from a passive pen or transmit/receive data to/from an active pen.

At least one of the input sensor 161-1 or the digitizer 161-2 may be implemented as a sensor layer formed on the display panel DP through a continuous process. The input sensor 161-1 and the digitizer 161-2 may be disposed on an upper side of the display panel DP, and one of the input sensor 161-1 and the digitizer 161-2, for example, the digitizer 161-2 may be disposed on a lower side of the display panel DP.

At least two of the input sensor 161-1 and the digitizer 161-2 may be integrated with a sensing panel through the same process. When at least two of the input sensor 161-1 and the digitizer 161-2 is integrated with a sensing panel, the sensing panel may be disposed between the display panel DP and a window disposed on an upper side of the display panel DP. According to an embodiment, the sensing panel may be disposed on the window, and a position of the sensing panel is not necessarily limited.

At least one of the input sensor 161-1 or the digitizer 161-2 may be embedded in the display panel DP. For example, at least one of the input sensor 161-1 or the digitizer 161-2 may be simultaneously formed through a process of forming elements (for example, a light-emitting element, a transistor, etc.) included in the display panel DP.

The sensor module 161 may generate a data value or an electric signal corresponding to an internal state or an external state of the electronic device ED. The sensor module 161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 162 may include one or more antennas for transmitting or receiving a signal or power to or from an exterior. According to an embodiment, the communication module 173 may transmit or receive a signal to or from the external electronic device through an antenna suitable for a communication technique. An antenna pattern of the antenna module 162 may be integrated with a component (for example, the display panel DP) of the display device DD, the input sensor 161-1, or the like.

The sound output module 163 may be a device for outputting a sound signal to an exterior of the electronic device ED and include, for example, a speaker used for general purposes such as playing multimedia or playing a recording and a receiver used for receiving a call. According to an embodiment, the receiver may be formed integrally with or separately from the speaker. A sound output pattern of the sound output module 163 may be integrated with the display device DD.

The camera module 171 may capture a still image and a moving image. According to an embodiment, the camera module 171 may include one or more lenses, an image sensor, or an image signal processor. The camera module 171 may further include an infrared camera capable of measuring presence/absence of a user, a position of a user, a gaze of a user, etc.

The light module 172 may provide light. The light module 172 may include a light-emitting diode or a xenon lamp. The light module 172 may operate in association with the camera module 171 or operate independently.

The communication module 173 may support establishing a wired or wireless communication channel between the electronic device ED and the external electronic device 102 and performing communication via the established communication channel. The communication module 173 may include any one or both of a wireless communication module such as a cellular communication module, a short-range wireless communication module, or a global navigation satellite system (GNSS) communication module and a wired communication module such as a local area network (LAN) communication module or a power line communication module.

The communication module 173 may communicate with the external electronic device 102 via a short-range communication network such as Bluetooth®, Wi-Fi direct, or infrared data association (IrDA) or a long-range communication network such as a cellular network, internet, or a computer network (for example, LAN or WAN). The various types of the communication module 173 described above may be implemented as a chip or may be each implemented as a separate chip.

The input module 130, the sensor module 161, the camera module 171, etc., may be used to control an operation of the display device DD in association with the processor 110.

The processor 110 may output a command or data to the display device DD, the sound output module 163, the camera module 171, or the light module 172 on the basis of input data received from the input module 130. For example, the processor 110 may generate image data corresponding to input data applied through a mouse, an active pen, or the like and output the image data to the display device DD, or may generate command data corresponding to input data and output the command data to the camera module 171 or the light module 172.

When input data is not received from the input module 130 for a certain amount of time, the processor 110 may change an operation mode of the electronic device ED to a low power mode or a sleep mode, thereby reducing power consumption of the electronic device ED.

The processor 110 may output a command or data to the display device DD, the sound output module 163, the camera module 171 or the light module 172 on the basis of sensing data received from the sensor module 161.

The processor 110 may execute a command or output corresponding image data to the display device DD on the basis of sensing data sensed by the input sensor 161-1 or the digitizer 161-2. When a temperature sensor is included in the sensor module 161, the processor 110 may receive temperature data about a temperature measured from the sensor module 161 and further perform luminance correction on image data, etc., on the basis of the temperature data.

The processor 110 may receive measurement data about presence/absence of a user, a position of a user, a gaze of a user, etc., from the camera module 171. The processor 110 may further perform luminance correction on image data, etc., on the basis of the measurement data. For example, the processor 110 may determine presence/absence of a user through an input from the camera module 171, and then may output image data of which luminance is corrected through the data conversion circuit 112-2 or the gamma correction circuit 112-3 to the display device DD.

Some of the above-described components may be connected to each other via a communication technique between peripheral devices, for example, bus, general purpose input/output (GPIO), serial peripheral interface (SPI), mobile industry processor interface (MIPI), or ultra path interconnect (UPI) link and may exchange a signal (for example, a command or data). The processor 110 may communicate with the display device DD through a mutually agreed interface, and for example, may use any one of the communication techniques described above and is not necessarily limited to the communication techniques described above.

The electronic device ED according to various embodiments disclosed herein may be various types of devices. For example, the electronic device ED may include at least one of a portable communication device (for example, a smartphone), a computer device, a portable multimedia device, a portable medical device, a camera, a wearable device, or a home appliance. The electronic device ED according to an embodiment herein is not necessarily limited to the devices described above.

According to the description above, an upper surface of a cushion layer may vary according to external pressure. Light emitted by pixels may reflect off of an external object. A path or the amount of light reflected off of the external object may vary depending on the external pressure. The amount of light received by sensors may vary according to a change in the amount of light. A size of a sensing area of the sensors may also vary. A timing controller may determine external pressure exerted by the external object according to sensing signals pertaining to the size of the sensing area and the amount of light received by the sensors. As such, the display device and the electronic device can indirectly determine an external pressure exerted by an external object on a front of the display device by sensing the amount of received light reflected by the external object and a size of an area encompassed by sensors that receive the reflected light. The deformable characteristics of a cushion layer disposed on a front side of a window can facilitate determination of an external pressure exerted by increasing deformation and reflection of incident light upon an increase of exerted pressure.

In the above, description has been made with reference to embodiments of the disclosure, but those skilled or of ordinary skill in the art may understand that various modifications and changes may be made to the disclosure insofar as such modifications and changes do not depart from the spirit and technical scope of the disclosure set forth in the claims to be described later. Therefore, the technical scope of the disclosure is not to be limited to the contents stated in the detailed description of the specification, but should be determined by the claims.

What is claimed is:

1. A display device comprising:
a display panel including:
a substrate;
a plurality of sensors disposed on the substrate, each of the plurality of sensors includes a light-receiving element; and
a plurality of pixels, each of the plurality of pixels include a light-emitting element adjacent to the light-receiving element;
a window disposed on the display panel; and
a cushion layer disposed on the window,
wherein an upper surface of the cushion layer is deformable upon application of an external pressure.

2. The display device of claim 1, wherein
light generated by the plurality of pixels is incident onto an external object,
the external object is configured to exert the external pressure to the cushion layer, and
the plurality of sensors are configured to receive and sense light reflected off the external object.

3. The display device of claim 2, wherein an amount of deformation of the cushion layer increases and an amount of light received by the plurality of sensors increases as the external pressure increases.

4. The display device of claim 3, wherein an amount of deformation of the cushion layer increases and a number of the plurality of sensors which receive light reflected off the external object increases as the external pressure increases.

5. The display device of claim 3, wherein an amount of deformation of the cushion layer increases and a size of a sensing area of the display panel which receives light reflected off the external object increases as the external pressure increases.

6. The display device of claim 2, wherein an amount of deformation of the cushion layer decreases and an amount of light received by the plurality of sensors decreases as the external pressure decreases.

7. The display device of claim 6, wherein an amount of deformation of the cushion layer decreases and a number of the plurality of sensors which receive light reflected off the external object decreases as the external pressure decreases.

8. The display device of claim 6, wherein an amount of deformation of the cushion layer decreases and a size of a sensing area of the display panel which receives light reflected off the external object decreases as the external pressure decreases.

9. The display device of claim 1, further comprising:
a timing controller configured to receive sensing signals from the plurality of sensors, wherein
light generated by the plurality of pixels is incident onto an external object which applies the external pressure to the cushion layer.

10. The display device of claim 9, wherein
the timing controller is configured to determine the external pressure exerted by the external object according to sensing signals received from the plurality of sensors, and
the sensing signals pertain to a size of a sensing area and an amount of light received by the plurality of sensors.

11. The display device of claim 9, wherein the timing controller is configured to determine an increase in the external pressure upon an increase in a size of a sensing area.

12. The display device of claim 11, wherein the timing controller is configured to determine a decrease in the external pressure upon a decrease in the size of the sensing area.

13. The display device of claim 9, wherein the timing controller is configured to output fingerprint information corresponding to the sensing signals.

14. The display device of claim 1, wherein the cushion layer comprises:
a transparent polymer; and
a transparent urethane material.

15. The display device of claim 1, wherein
light generated by the plurality of pixels is incident onto an external object which applies the external pressure to the cushion layer, and
an angle between the light incident onto the external object and light reflected off the external object and incident onto the plurality of sensors is about 71 degrees or less.

16. A display device comprising:
a display panel which includes:
a substrate;
a plurality of sensors disposed on the substrate, each of the plurality of sensors includes a light-receiving element; and
a plurality of pixels, each of the plurality of pixels include a light-emitting element adjacent to the light-receiving element;
a window disposed on the display panel; and
a timing controller configured to receive sensing signals from the plurality of sensors, wherein
light generated by the plurality of pixels is incident onto an external object that is in contact with the window,
the plurality of sensors are configured to receive and sense light reflected off the external object, and
the timing controller is configured to determine an amount of external pressure exerted by the external object according to sensing signals pertaining to a size of a sensing area and an amount of light received by the plurality of sensors.

17. The display device of claim 16, wherein
an amount of light received by the plurality of sensors increases and a size of the sensing area of the display panel increases as a contact area between the external object and the window increases, and
an amount of light received by the plurality of sensors decreases and a size of the sensing area of the display panel decreases as the contact area between the external object and the window decreases.

18. The display device of claim 16, wherein
the external object is in direct contact with the window, and
the window remains rigid upon pressure being exerted by the external object.

19. An electronic device comprising:
a camera module; and
a display device configured to display an image corresponding to an image captured by the camera module, wherein the display device includes:
a display panel including:
a substrate;
a plurality of sensors disposed on the substrate, each of the plurality of sensors includes a light-receiving element; and
a plurality of pixels, each of the plurality of pixels includes a light-emitting element adjacent to the light-receiving element,
a window disposed on the display panel, and
a cushion layer disposed on the window, wherein an upper surface of the cushion layer is deformable according to an external pressure.

20. The electronic device of claim 19, wherein
the cushion layer is configured to be optically transparent to light produced by the plurality of pixels, and
the plurality of sensors sense both an amount of light reflected off of an external object exerting the external pressure and a size of a sensing area corresponding to an area of ones of the plurality of sensors that receive the light reflected off of the external object.
